(19) United States
(12) Patent Application Publication
(10) Pub. No.: US 2021/0404801 A1
(43) Pub. Date: Dec. 30, 2021

(54) Pattern Measurement Method, Measurement System, and Computer-Readable Medium

(71) Applicant: Hitachi High-Tech Corporation, Minato-ku, Tokyo (JP)

(72) Inventors: Ayumi DOI, Tokyo (JP); Makoto SUZUKI, Tokyo (JP); Daisuke BIZEN, Tokyo (JP); Shunsuke MIZUTANI, Tokyo (JP)

(21) Appl. No.: 17/290,018

(22) PCT Filed: Nov. 5, 2018
(86) PCT No.: PCT/JP2018/041036

§ 371 Date: Apr. 29, 2021

(51) Int. Cl. G01B 21/18; H01J 37/28; G01B 15/04

(52) U.S. Cl. CPC G01B 21/18; H01J 37/28; G01B 2210/56; H01J 2237/281; H01J 2237/2815; G01B 15/04

(57) ABSTRACT

The present disclosure pertains to a method, a system, and a computer-readable medium for highly precisely measuring the depth of a recess formed in a sample even when, inter alia, the material or pattern density of the sample differs. In order to achieve the purpose described above, there are proposed a method, a measurement system, and a non-temporary computer-readable medium for storing program commands that can be executed by a computer system, the method, system, and medium involving: using a measurement tool to acquire an image or a brightness distribution of a region including a recess formed in a sample; extracting a first characteristic of the interior of the recess, and a second characteristic pertaining to the dimensions or area of the recess, from the acquired image or brightness distribution; and inputting the extracted first characteristic and second characteristic to a model that indicates the relationship between the first characteristic, the second characteristic, and a depth index of the recess to thereby derive the depth index of the recess.

### TECHNICAL FIELD

The present disclosure relates to a method and device for measuring a height or depth of a pattern, and in particular, a method, a system, and a computer-readable medium for measuring a depth of a recess such as a hole and a trench.

### BACKGROUND ART

PTL 1 discloses a scanning electron microscope that estimates a depth of a hole or a trench based on, when a hole or a trench formed in a sample is irradiated with an electron beam, detection of backscattered electrons that are reflected at a bottom of the hole or the trench and are emitted onto the sample after passing through a side wall of the hole or the trench. PTL 1 discloses a method of estimating the depth based on luminance (signal amount) information by utilizing a phenomenon that the deeper the hole or trench is, the longer the passing distance is, and the deeper the hole or trench is, the darker the image is.

### CITATION LIST

### Patent Literature

PTL 1: Japanese Patent Number 6316578 (Corresponding U.S. Pat. No. 9,852,881)

### SUMMARY OF INVENTION

### Technical Problem

According to the method disclosed in PTL 1, although the pattern depth can be measured based on the luminance information, the required depth change depending on a difference in sample material and a difference in pattern density due to a principle of evaluating the luminance that changes according to an amount of electrons emitted after passing through the sample.

Hereinafter, a method, a system, and a computer-readable medium for measuring a depth of a recess formed in a sample with high accuracy even when a material or a pattern density of the sample is different are proposed.

### Solution to Problem

As an aspect in order to achieve the purpose described above, there are proposed a method, a non-temporary computer-readable medium for storing a program command that can be executed on one or more computer systems for executing the method, and a system for executing the method, and the method includes: acquiring, by using a measurement tool, an image or brightness distribution of a region including a recess formed in a sample; extracting, from the acquired image or brightness distribution, a first characteristic of an interior of the recess, and a second characteristic related to a dimension or area of the recess; and inputting the extracted first characteristic and second characteristic into a model indicating a relationship between the first characteristic, the second characteristic, and a depth index of the recess to derive the depth index of the recess.

### Advantageous Effect

According to the above method or configuration, the depth of the recess formed in the sample can be measured with high accuracy even when a material or a pattern density of the sample is different.

### BRIEF DESCRIPTION OF DRAWINGS

FIG. 1 shows an example of a depth measurement system.

FIG. 2 shows another example of the depth measurement system.

FIG. 3 shows another example of the depth measurement system.

FIG. 4 shows another example of the depth measurement system.

FIG. 5 is a flowchart showing a depth measurement process.

FIG. 6 is a flowchart showing a depth measurement process.

FIGS. 7A-7C show a movement trajectory of electrons that have entered the sample.

FIGS. 8A and 8B show a database of incident electrons and an example of a device condition setting screen of an electron microscope.

FIGS. 9A-9C show an example of a setting screen for setting a recipe which is an operation program of an electron microscope.

FIGS. 10A-10D show an example of the setting screen for setting the recipe which is the operation program of the electron microscope.

FIGS. 11A and 11B show an example of a database that stores depths and depth indexes in association with each other.

FIGS. 12A and 12B show an enlarged image and a cross-sectional image of a trench pattern.

FIGS. 13A and 13B show an image in a state where the sample is not irradiated with an electron beam (a state in which no electrons detected due to electron beam irradiation exists) and a brightness distribution of the image.

FIGS. 14A-14C show an example of a low frame image and a brightness distribution thereof.

FIGS. 15A-15D show an example of a GUI screen for setting a luminance value and a contrast value.

FIGS. 16A-16C show an example of an image obtained when trenches are scanned with a beam.

FIGS. 17A and 17B show an example of an image obtained when a hole pattern is scanned with a beam.

FIGS. 18A and 18B show an example of an image obtained when an elliptical pattern is scanned with a beam.

FIGS. 19A and 19B show an example of an image obtained when a rectangle pattern is scanned with a beam.

FIGS. 20A and 20B show an example of an image obtained when a plurality of hole patterns are scanned with a beam.

FIGS. 21A and 21B show an example of an image obtained when a via in trench is scanned with a beam.

FIGS. 22A and 22B show an example of a brightness evaluation region of a pattern.

FIGS. 23A-23C show an example of an evaluation result display screen.

FIGS. 24A-24C show an example of the evaluation result display screen.

FIG. 25 shows an example of a computer system that obtains depth information.

### DESCRIPTION OF EMBODIMENTS

With complexity and miniaturisation of semiconductor devices, etching has become an important process that affects quality of the devices. An embodiment to be described below mainly relates to a method of measuring a height or depth of a pattern using a scanning electron microscope, and in particular, relates to a depth measurement technique using an image gray level (brightness) at low acceleration (energy when an electron beam reaches a sample is low). Since a depth measurement at low acceleration is better in depth sensitivity than at high acceleration and is not affected by peripheral patterns, a highly accurate depth measurement can be performed without necessarily preparing a calibration curve for each structure.

From simulations and experiments, inventors newly found that a linearity exists between an Nth power of (hole area/hole bottom gray level) in a hole structure or an Nth power of (trench width/trench bottom gray level) in a trench structure, and a depth of the hole or the trench. A depth measurement method using the linearity will be described below. It was confirmed that N is a positive number, and is preferably 0.5 or 1 according to evaluations so far.

The measurement target is a pattern with a recess such as a hole or a trench, and a depth of the pattern is measured by measuring a brightness value (gray level) at a bottom of the hole or the trench, and an area for a surrounded pattern such as the hole or a width for an un-surrounded pattern such as the trench, and calculating an Nth power of the index value (area or width/brightness value). A depth index may indicate an actual depth value, or may be a value that changes according to a degree of depth.

According to a simulation by the inventors, it was confirmed that in a state in which electron microscope conditions (energy, angle discrimination, presence/absence of pulling electric field) are fixed, when patterns having different hole diameters and depths are irradiated with a beam, the smaller and deeper the hole diameter is, the smaller a signal amount at a hole bottom is. Further, it was confirmed that the pattern depth and √(area/signal amount at hole bottom) are in a linear relationship, and the pattern depth can be measured by setting a value obtained based on √(area/signal amount at hole bottom) as an index value. It was confirmed that, in a case of the trench structure, the pattern depth and (trench width/signal amount at trench bottom) are in a linear relationship, and the depth of the trench can be measured based on (trench width/signal amount at trench bottom).

A depth measurement system for measuring a depth (height) of a pattern and the like formed in the sample will be described below with reference to the drawings.

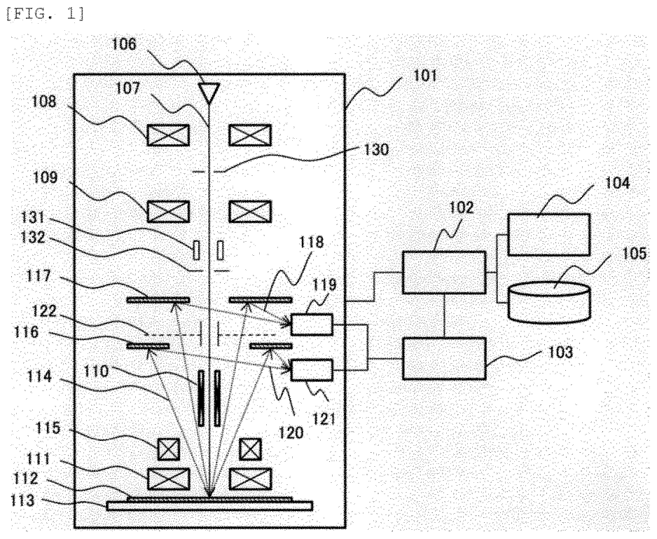

FIG. 1 is a diagram showing an example of a depth measurement device, and is a diagram showing an example of a depth (height) measurement system including a scanning electron microscope (measurement tool). The depth measurement system includes an imaging unit 101, an overall control unit 102, a signal processing unit 103, an input and output unit 104, and a storage unit 105.

The imaging unit 101 includes an electron gun 106, a focusing lens 103 that focuses the electron beam 107 (electron beam) emitted from the electron gun 106, and a focusing lens 109 that further focuses the electron beam that has passed through the focusing lens 108. The imaging unit 101 further includes a deflector 110 that deflects the electron beam 107, and an objective lens 111 that controls a focusing height, of the electron beam 107.

The electron beam that has passed through the optical elements provided in the scanning electron microscope as described above irradiates a sample 112 placed on a stage 113. Emitted electrons 114 such as secondary electrons (SE) and backscattered electrons (BSE) emitted from the sample due to the electron beam irradiation are guided in a predetermined direction by a deflector 115 (secondary electron aligner) for deflecting the emitted electrons. The deflector 115 is a so-called Wien filter that selectively deflects emitted electrons 114 in a predetermined direction instead of deflecting the electron beam.

The emitted electrons 114 that have passed through a detection aperture 116 provided for angle discrimination of the emitted electrons 114 collide with a reflecting plate 117, and secondary electrons (tertiary electrons 118) emitted from the reflecting plate 117 due to the collision are guided to a detector 119 by a Wien filter or the like (not shown), A detector 121 for detecting secondary electrons (tertiary electrons 120) generated due to collision of emitted electrons 114 with the detection aperture 116 is also provided.

The scanning electron microscope illustrated in FIG. 1 is provided with a shutter 130 that partially restricts the passage of the electron beam, a blanking deflector 131 that restricts arrival of the electron beam to the sample 112 by deflecting the electron beam off an optical axis, and a blanking electrode 132 that receives the electron beam deflected by the blanking deflector 131.

The optical elements provided in the scanning electron microscope as described above are controlled by the overall control unit 102. An opening provided in the reflecting plate 117 allows the electron beam 107 to pass through, and by making the opening sufficiently small, the secondary electrons emitted vertically upward from a hole bottom or a trench bottom of the semiconductor pattern formed in the sample 112 can be selectively detected. On the other hand, the secondary electrons are deflected by the deflector 115, such that the secondary electrons emitted vertically upward do not pass through the opening of the reflecting plate 117. The energy of the secondary electrons emitted vertically upward can be sorted by an energy filter 122 provided between the reflecting plate 117 and the detection aperture 116.

The signal processing unit 103 generates an SEM image based on the outputs of the detectors 119 and 121. The signal processing unit 103 generates image data by storing a detection signal in a frame memory or the like in synchronization with scanning performed by a scanning deflector (not shown). During storing of the detection signal into the frame memory, a signal profile (one-dimensional information) and an SEM image (two-dimensional information) are generated by storing a detection signal at a position of the frame memory corresponding to a scanning position.

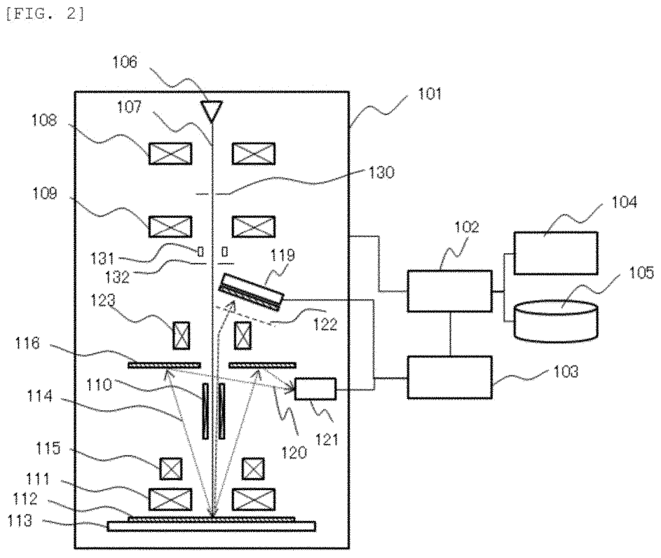

FIG. 2 is a diagram showing another example of the depth measurement device. Similar as the device in FIG. 1, the depth measurement device includes the imaging unit 101, the overall control unit 102, the signal processing unit 103, the input and output unit 104, and the storage unit 105. The device illustrated in FIG. 2 is different from the device illustrated in FIG. 1 is that a deflector 123 (second secondary electron aligner) for guiding the emitted electrons 114 to the detector 119 arranged off axis is provided. The detector 119 in FIG. 2 has a detection surface at a position where the emitted electrons 114 collide, and for example, the emitted electrons incident on the detection surface are converted into an optical signal by a scintillator provided on the detection surface. The optical signal is amplified by a photomultiplier and converted into an electric signal, which becomes an output of the detector. The emitted electrons 114 having a passing orbit near the optical axis can be energy-discriminated by an energy filter 122 provided immediately before the detector 119.

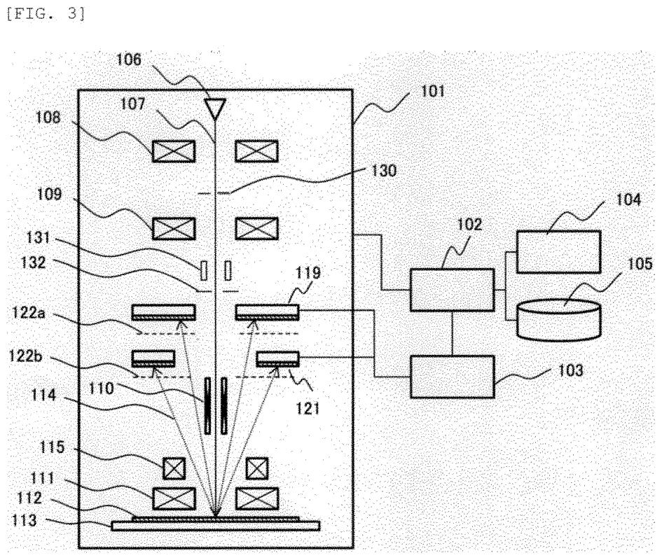

FIG. 3 is a diagram showing another example of the depth measurement device. A difference from FIG. 1 is that upper and lower two-stage detectors 119 and 121 are both direct detectors disposed in the orbit of the emitted electrons 114. An opening provided in the detector 119 allows the electron beam 107 to pass through, and by making the opening sufficiently small, the secondary electrons emitted from a bottom of the deep hole or deep trench formed in the sample 112, passing near a center of the pattern and escaped onto the surface of sample can be detected. By deflecting the secondary electrons with the deflector 115 as necessary, the electrons passing near the optical axis escaped from the deep hole or the like can be guided to an outside of the opening of the detector 119 (the detection surface of the detector 119). The emitted electrons 114 can be energy-discriminated based on energy filtering using an energy filter 122a immediately before the detector 119 or an energy filter 122b immediately before the detector 121.

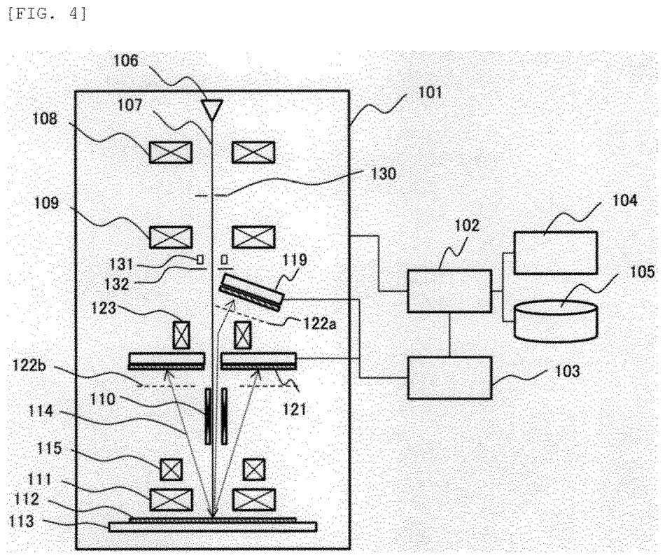

FIG. 4 is a diagram showing still another example of the depth measurement device. The lower-stage detector in FIG. 2 employs a method of guiding the secondary electrons (since the emitted electrons themselves are secondary electrons, electrons further generated by the collision of the emitted electrons may be referred to as the tertiary electrons), generated by the emitted electrons 114 colliding with a secondary electron conversion electrode such as the reflecting plate 116, to the detector and detecting the secondary electrons, and on the other hand, in FIG. 4, the lower-stage detector 121 is disposed in the orbit of the emitted electrons 114 instead.

The deflector 123 deflects the emitted electrons that have passed through an electron beam passage opening of the detector 121 toward the detector 119, and thus the emitted electrons that pass near the optical axis can be selectively detected by the detector 119. The emitted electrons deflected by the deflector 123 are electrons that reach an upper part of the detector 121 instead of being blocked by the detector 121, that is, only electrons that pass near the optical axis are selected. Compared with other emitted electrons, such emitted electrons contain more electrons at the bottom of the deep hole or the deep trench, and by forming a signal waveform or an image based on the electrons detected by the detector 119, information on the hole bottom and the trench bottom may be emphasized. By the energy filter 122a immediately before the detector 119 or the energy filter 122b immediately before the detector 121, energy of the secondary electrons 114 including the vertically upward secondary electrons can be sorted. In the present embodiment, although an example of obtaining the depth index of the recess formed in the sample by using the image and the brightness distribution obtained by electron beam scanning will be described, the invention is not limited thereto, and other measurement tools such as a focused ion beam device may be used.

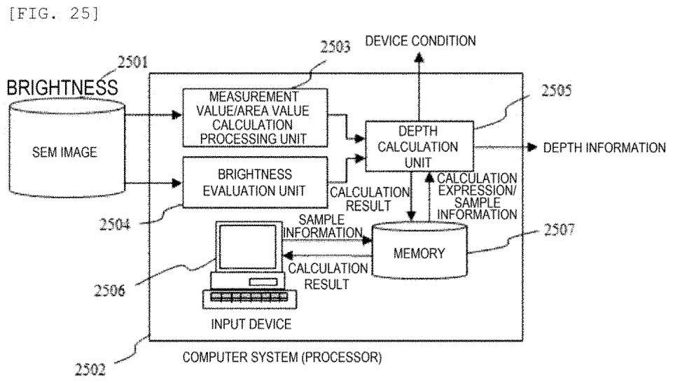

FIG. 25 shows a computer system 2502 that obtains depth information from an SEM image 2501 generated based on an output of the scanning electron microscope as illustrated in FIGS. 1 to 4. The computer system 2502 may include one or more computer subsystems, and includes one or more components to be executed by the computer system 2502. The computer system 2501 illustrated in FIG. 25 can be set as a signal processing unit 103 of the scanning electron microscope illustrated in FIGS. 1 to 4 or a part thereof so as to be a module of the scanning electron microscope.

A length measurement value/area value calculation processing unit 2503 uses the SEM image received from a predetermined storage medium or an image generation processor provided in the scanning electron microscope to obtain a dimension value of a pattern or an area value of a pattern displayed in the SEM image 2501. For example, in a case of the dimension value, a signal profile, which is brightness distribution information of an image, is generated based on the SEM image, a distance between peaks of the signal profile, and the like is obtained so as to calculate a one-dimensional dimension of the pattern. A specific method of obtaining the area value will be described later. For example, a brightness evaluation unit 2504 evaluates brightness (a gray level) of a part of the pattern for evaluating the depth (for example, in the case of a hole pattern, a center position of the hole pattern).

A depth calculation unit 2505 executes the depth (height) calculation of the pattern using a calculation expression to be described later, a length measurement value, an area value, and a brightness value. The calculation expression used for the depth calculation is a calculation expression that is stored in association with sample information based on a sample information input using an input device 2506, the calculation expression is read from a memory (database) 2507, and is used for depth calculation. The depth information calculated by the depth calculation unit is displayed on a display device or the like as an output of the computer system and stored in the predetermined storage medium.

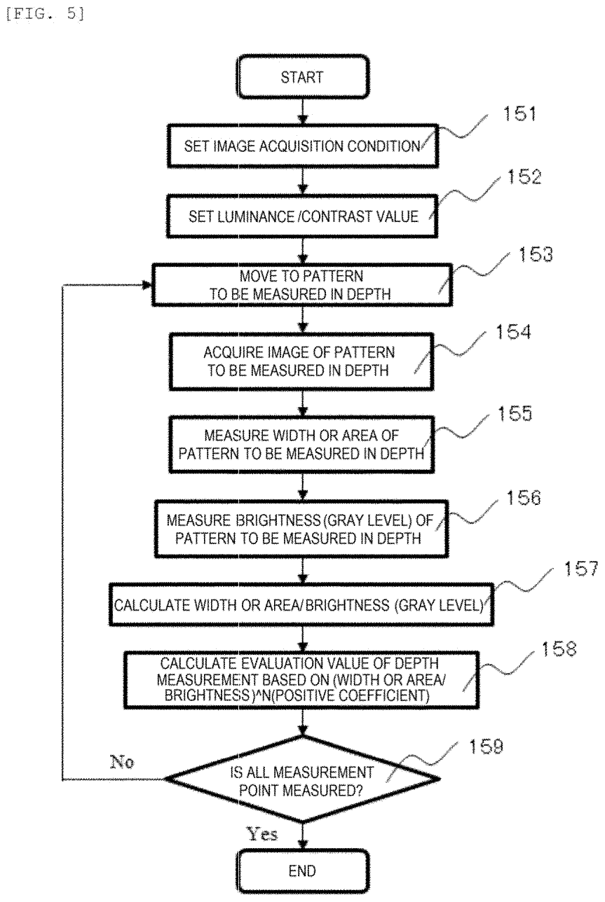

Hereinafter, a depth measurement procedure using the depth measurement system or the computer system will be described with reference to a flowchart illustrated in FIG. 5. FIG. 5 shows an example of a flow of obtaining a change or a trend of a depth of an in-wafer pattern or an inter-wafer pattern. When necessary information is input from the input and output unit 104 of the depth measurement device, an operation program (recipe) is generated and stored in the storage unit 105, and the imaging unit 101, the overall control unit 102, the signal processing unit 103, and the like control the respective components according to operation conditions stored in the recipe.

The imaging unit 101 or the like sets image acquisition conditions in accordance with information stored in the recipe (program) (step 151), and the signal processing unit 103 or the like adjusts a gain of a photoelectron multiplier tube and an offset of an amplifier such that the image has a predetermined luminance and contrast (step 152) . Further, the imaging unit 101 or the like controls a driving mechanism (a linear motor or the like) for moving the stage 113 so as to position a field of view of the scanning electron microscope in a pattern to be measured in depth (step 153).

Next, based on detection of electrons obtained by electron beam scanning, at least one (an image or the like) of a signal waveform or an image is generated and acquired (step 154), and the signal processing unit 103 or the computer system 2502 measures a width or an area of the pattern to be measured in depth (step 155). Further, the brightness (gray level) of the pattern to be measured in depth is measured (step 156), and the depth calculation unit 2505 calculates the depth index by using [Equation 1] (step 153).

Depth index D=(pattern width W or pattern area A/brightness B)^{N} [Equation 1]

N is a positive number. Equation 1 is a mathematical model indicating a relationship between the brightness B (first characteristic) of the bottom of the pattern (recess), the pattern width W or the pattern area A (second characteristic), and the depth index of the pattern, and the depth index of the pattern is derived by inputting the brightness B, the pattern width W, or the area A to the mathematical model. Although an example in which a depth index is derived using a brightness value of a brightness evaluation region will be described below, another parameter that changes according to the brightness value may be used instead of the brightness value. For example, a difference value with respect to a reference brightness value, an index value assigned to each predetermined brightness range, and the like may be considered. Furthermore, the area and dimension can be replaced with other parameters that change in accordance with the area and the dimension.

Next, the overall control unit 102 determines whether an unmeasured point exist on the sample (step 159), and when the unmeasured point exist, measurement of a desired measurement point is executed by repeating the processing of step 153 and subsequent steps.

By performing the above-described processing, three-dimensional information such as the depth or height of the pattern can be acquired from the two-dimensional image. Information of the pattern to be measured in depth and a measurement method are set in advance in the recipe.

The depth index D does not need to be an absolute value, and may be, for example, an index value indicating a degree of depth or a value that determines a relationship with a reference depth (for example, a depth deeper than, shallower than, and the same as the reference depth). Specifically, a level of a depth such as 1 to n may be output as the depth information depending on the degree of depth, or it may be determined whether D is larger than an index value Ds of the reference depth, and in a case where the depth index D is larger, a result of being deep may be output as the depth information, while in a case where the depth index D is smaller, a result of being shallow may be output as the depth information.

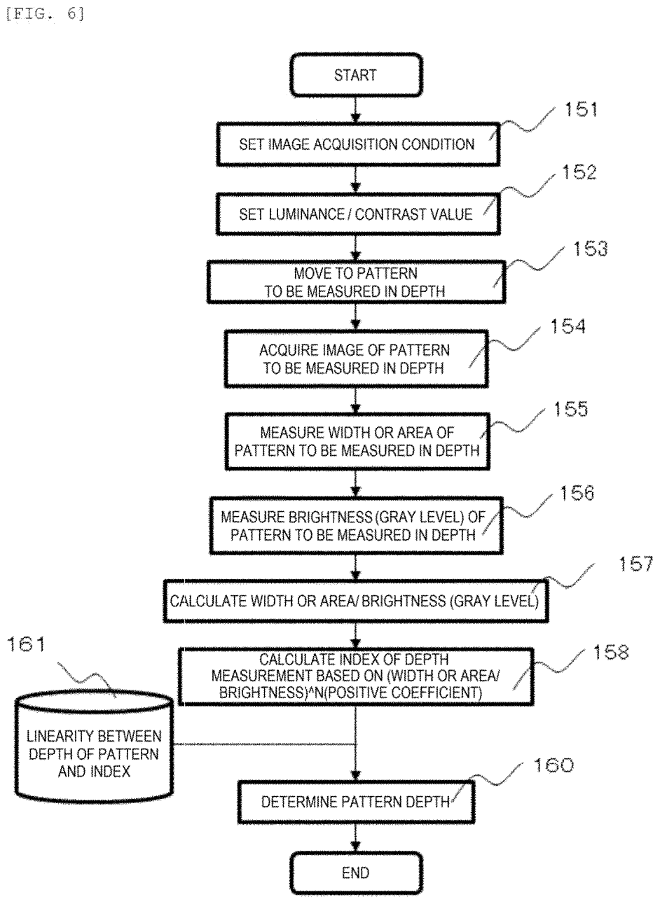

FIG. 6 is a flowchart showing a process of obtaining an absolute value of the pattern depth more accurately by referring to a database storing a relationship between the pattern depth and the index value. Steps 151 to 158 are the same as those in FIG. 5. According to a processing example illustrated in FIG. 6, the depth index D is referred to the database (step 161), and a depth corresponding to the index value is read out, and thereby the pattern depth is determined (step 160). A calculation expression or a function indicating the relationship between the depth index D and an actual depth is stored in advance in the memory 2507 or the like for each type of the sample or device condition of the scanning electron microscope, read out according to the input sample information and the set device conditions of the scanning electron microscope and used for the calculation for determining the depth, and thereby depth or height measurement is realized. The information of the pattern to be measured in depth and the measurement method can be set in advance in the recipe.

The acquisition conditions set in step 151 include energy of incident electrons with respect to the sample. An example of how to determine the energy of incident, electrons will be described below. Incident energy is obtained based on a difference between an acceleration voltage (Vacc) that accelerates the electron beam and a negative voltage (retarding voltage Vr) applied to the sample, and an overall control unit 102 applies the acceleration voltage and the negative voltage so as to meet beam conditions set in advance as the recipe.

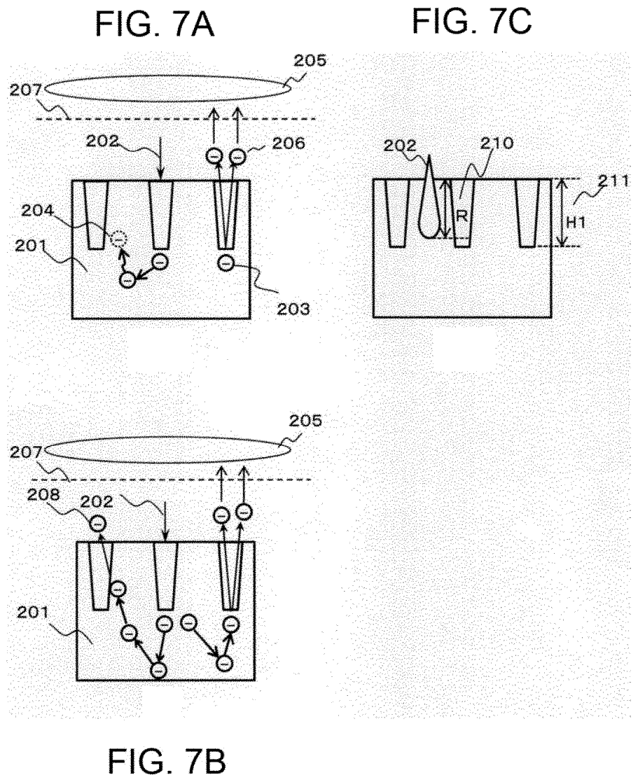

In the depth measurement described in the present embodiment, while detecting the electrons obtained based on the incident near the bottom of the pattern to be measured in depth, generation of electrons obtained based on the electrons penetrating deeper than the bottom are prevented, and thereby the highly accurate depth measurement is realized. Specifically, as illustrated in FIG. 7(a), when a sample 201 is irradiated with an electron beam 202 near a bottom of a trench or hole of the sample 201, electrons 203 generated near the bottom are emitted onto the sample 201. However, electrons 204 generated by the incident electrons penetrating deeper than the bottom is emitted in an extent of not emitted onto the sample 201. Energy discrimination performed by the energy filter 207 can also be performed by the detector 205 in order to selectively detect the electrons 206 generated at the hole bottom and emitted from the hole. As illustrated in FIG. 7(b), incident electrons penetrate deeper than near the hole bottom, and electrons 208 obtained consequently contains information other than the hole bottom, which is a main factor of reduction of the accuracy of the depth measurement. Therefore, it is desirable to select incident energy low to an extent that the electrons 208 are not generated.

Energy 202 of the electron beam used for the depth measurement may be determined such that an electron penetration length R210 as shown in Equation 2 is shorter than a film thickness 211 (assumed pattern depth) (refer to FIG. 7(c)).

R=27.6E₀^{1.67}A/ρZ^{8/9} [Equation 2]

R is a penetration depth (nm), E₀ is the energy (keV) of the incident electrons, A is an atomic weight, ρ is a density (g/cm³), and Z is an atomic number of the sample.

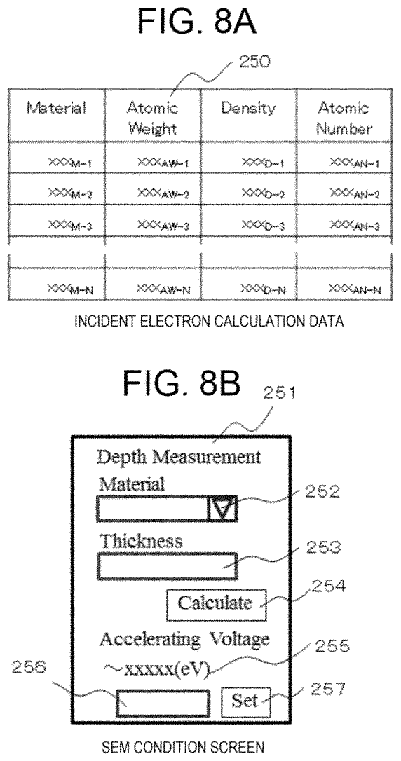

Hereinafter, a specific setting procedure of the incident energy and a scanning electron microscope whose device conditions are set according to the setting procedure will be described. FIG. 8(a) shows an example of a database used for determining the energy of the incident electrons or the film thickness of the sample, and FIG. 8(b) is a setting screen for beam conditions of the electron microscope. The data and setting screen are displayed on, for example, a display screen of an input device provided in the computer system 2502, and the user can input and confirm necessary information through the display screen. The database or the like is stored in the memory 2507 in advance, and the depth calculation unit 2505 executes a calculation of such as the incident energy based on the input of the sample information or the like using the input device 2506. Data 250 such as a material name, an atomic weight (A), a density (ρ) (g/cm³), and an atomic number (Z) of the sample material are stored in advance in a database as illustrated in FIG. 8(a).

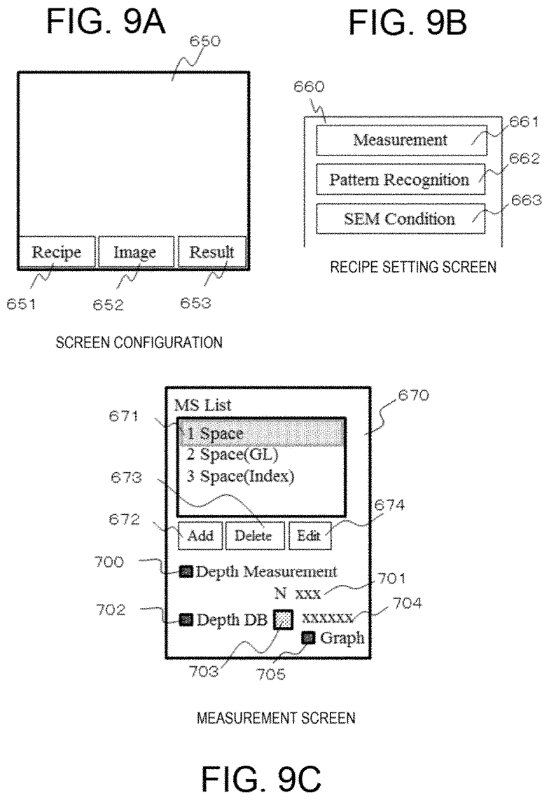

FIG. 9 shows an example of a recipe setting screen for setting operating conditions of the scanning electron microscope, and FIG. 9(a) is a diagram showing an example of a selection screen for selecting a setting target. When a recipe button 651 on a screen 650 is pressed, a recipe setting screen (FIG. 9(b)) is opened, and when an SEM condition button 663 is pressed, an SEM condition screen 251 illustrated in FIG. 8(b) is opened. Incident electron energy can be set by inputting information on the SEM condition screen 251.

The sample material is selected from a material tab 252 of the SEM condition screen 251, A material name in the stored data 250 is displayed on the material tab 252. When an expected film thickness (nm) 253 of the sample is input to the thickness 253 and a calculate button 254 is pressed, energy E₀ of the incident electrons based on the Equation 2 can be calculated with the film thickness input to the thickness 253 as R in Equation 2. The obtained E₀ is displayed on an accelerating voltage 255. Since the obtained energy E₀ of the incident electrons is an upper limit in the depth measurement, optimum incident energy can be determined by using energy of incident electrons less than the energy E₀. Referring to the accelerating voltage 255, the energy of the incident electrons to be set in an incident energy setting column 256 is input, and when a Set button 257 is pressed, the energy of the incident electrons is set in the recipe and stored in the storage unit 105 or the memory 2507.

Next, a method of setting measurement parameters other than the incident, energy will be described. The parameters (setting information) are input from the input and output unit 104 or the like of the device and are stored in the storage unit 105 or the like as the recipe. In addition to the recipe button 651, the screen 650 is provided with an image button 652 and a result button 652.

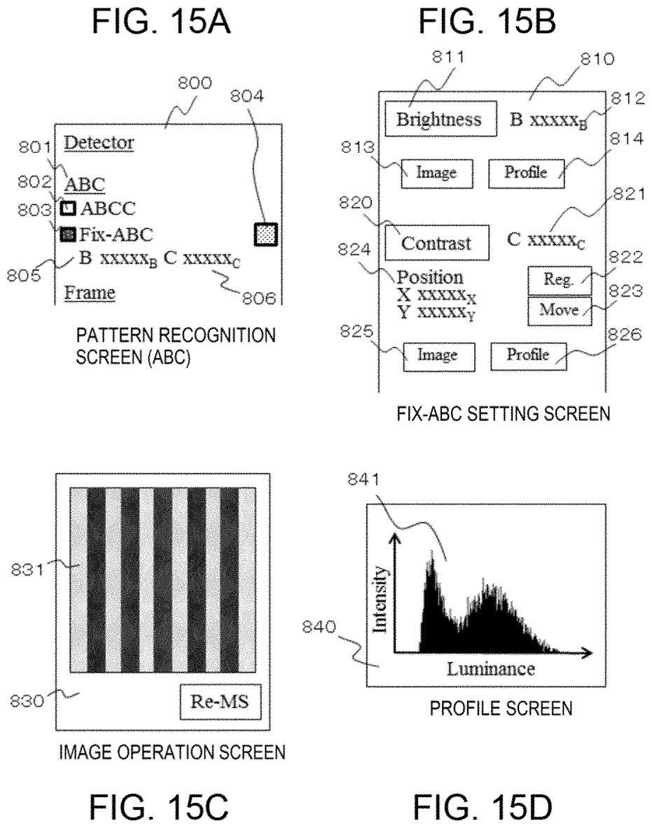

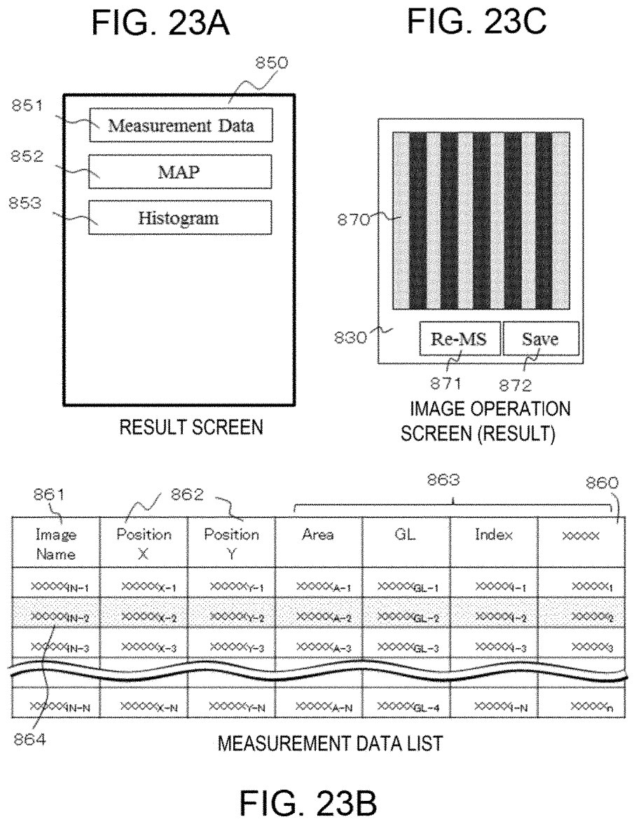

When the recipe button 651 is pressed, the recipe setting screen 660 is opened, and parameters required for depth measurement can be set. When the image button 652 is pressed, an image operation screen 830 as illustrated in FIG. 15(c) is displayed, and a captured image can be confirmed. When a result button 653 is pressed, a result screen 350 as illustrated in FIG. 23 is displayed, and a measurement result can be confirmed.

The recipe setting screen 660 illustrated in FIG. 9(b) is provided with a measurement button 661, a pattern recognition button 662, and the SEM condition button 663.

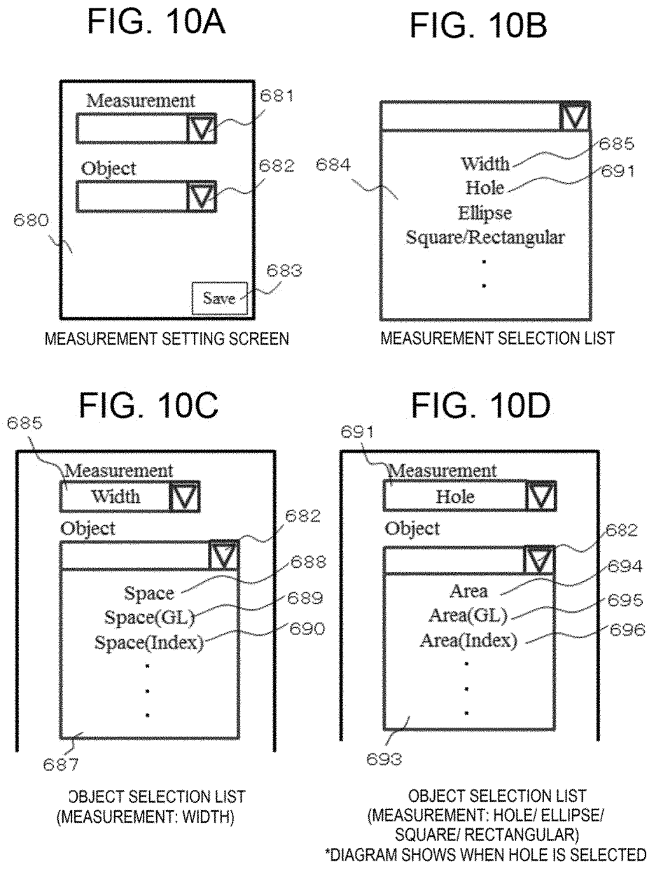

When the measurement button 661 is pressed, a measurement screen 670 illustrated in FIG. 9(c) is opened, and parameters required for a measurement can be set. In an MS list 671, a list of set measurement contents can be confirmed. When an add button 672 is pressed, a measurement setting screen 680 illustrated in FIG. 10(a) is opened, and a measurement method corresponding to the pattern to be measured can be selected. When a registered measurement is to be deleted, the measurement can be deleted by selecting the measurement from the MS list 671, and pressing a delete button 673. When the registered measurement content is to be edited, an edit button 674 is pressed, the measurement setting screen 680 is opened, and thereby the editing can be performed.

An example of the procedure for registering/editing measurement parameters on the measurement setting screen 680 illustrated in FIG. 10(a) is shown below. When a measurement tab 681 on the measurement setting screen 680 is opened, a measurement, selection list 684 illustrated in FIG. 10(b) is opened, and the measurement method corresponding to the pattern can be selected.

Next, a procedure for selecting the measurement method corresponding to a shape of the pattern will be described. For example, when a measurement condition of a trench is to be set, a width 685 in the measurement tab 681 of the measurement, selection list 680 is selected. When an object tab 682 is opened during selection of the width, an item 687 for measuring the trench is displayed as illustrated in FIG. 10(c). When the depth measurement is to be performed, the measurement target is selected as illustrated in FIG. 10(c).

First, a width (space) of the trench is selected as the measurement target by selecting a space 688. By selecting a space (GL) 689, brightness in the trench (space) is selected as the measurement target. Further, by selecting a space (index) 650, a mathematical model (calculation expression) such as Equation 3 is read from a predetermined storage medium, and a setting for executing a calculation of a depth index (I) is performed based on the calculation expression, a width (W) of the trench, and a brightness (GL) in the trench. N is a positive number.

I=(W/GL)^{N} [Equation 3]

FIG. 10(d) is a diagram showing an example of an object selection screen when a hole pattern is selected as the measurement target. When an elliptical pattern, a square pattern, and a rectangular pattern are selected rather than the hole pattern, the same object is selected. When the hole is measured in the depth measurement, a hole 691 is selected in the measurement selection list 680. When the object tab 682 is opened at the time of hole selection in the measurement tab 681, an item 693 for measuring the hole can be selected.

When a depth of the hole is the measurement target, first, an area of the hole is selected as the measurement target by selecting an area 694. By selecting an area (GL) 695, brightness in the hole is selected as the measurement target. Further, by selecting an area (index) 696, a mathematical model such as Equation 4 is read from a predetermined storage medium, and a setting for executing a calculation of the depth index (I) is executed based on the calculation expression, a hole pattern area (A), and a brightness (GL) of an interior of the hole. N is a positive number.

I=(A/GL)^{N} [Equation 4]

When a save button 683 is pressed, the measurement parameters set in the measurement 681 and the object 682 are added to the MS list 671 on the measurement screen 670 illustrated in FIG. 9(c).

Further, in a measurement condition setting process, a depth measurement 700 of the measurement screen 670 is enabled by using a GUI screen as illustrated in FIG. 9. Enabling the depth measurement 700 means that if the measurement parameters required for the depth measurement is set in the MS list 671, the processing illustrated in FIG. 5 is automatically executed. In an image acquisition condition setting process, a numerical value of an index N 701 in the case of performing a calculation such as Equation 3 and Equation 4 can be input.

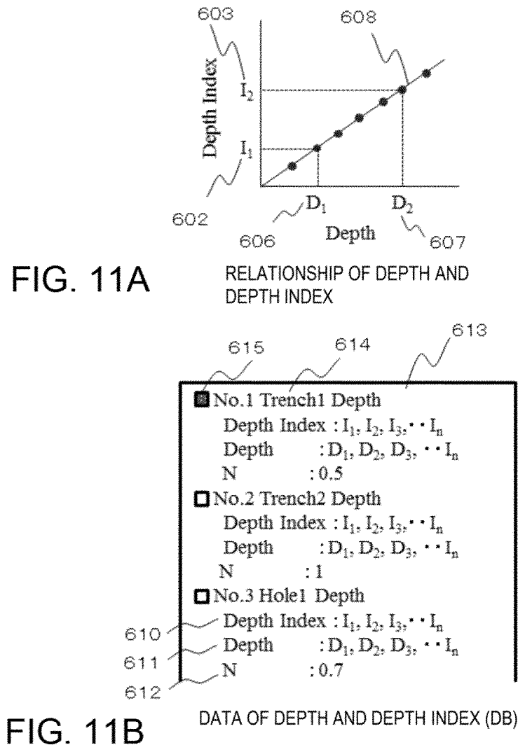

As illustrated in FIG. 6, in the case of obtaining a depth by referring to the database storing the relationship between the pattern depth and the index value, the database can be referred to by enabling the depth DB 702 illustrated in FIG. 9(c). When a button 703 in FIG. 9(c) is pressed, a list 613 of databases registered in advance as illustrated in FIG. 11(b) is displayed. In the list 613, a plurality of databases are displayed in which identification information 614 (for example, information that can identify the type of the pattern) 614, a depth index 610, a depth 611, and an index 612 used for the calculation of the depth index are stored in association with one other. The database is selected by checking a check button 615 on a GUI screen as illustrated in FIG. 11(b). The identification information 614 can be displayed on 704 of the measurement screen 670 illustrated in FIG. 9(c) and confirmed thereon. If the data to be used is specified, a graph 608 of the depth and the index value of the depth can be displayed and confirmed by pressing a graph button 706.

In a database 161 used in the processing process illustrated in FIG. 6, the relationship information between the depth index and the actual pattern depth is stored. The actual depth of a target pattern can be obtained based on a depth measurement using an atomic force microscope (AFM), or a measurement performed in advance in which a depth is measured based on a cross-sectional image of a hole pattern or the like. The method of measuring the depth of the target pattern is not limited to the cross-sectional analysis and the AFM, and may be any method as long as the depth of the target pattern can be known.

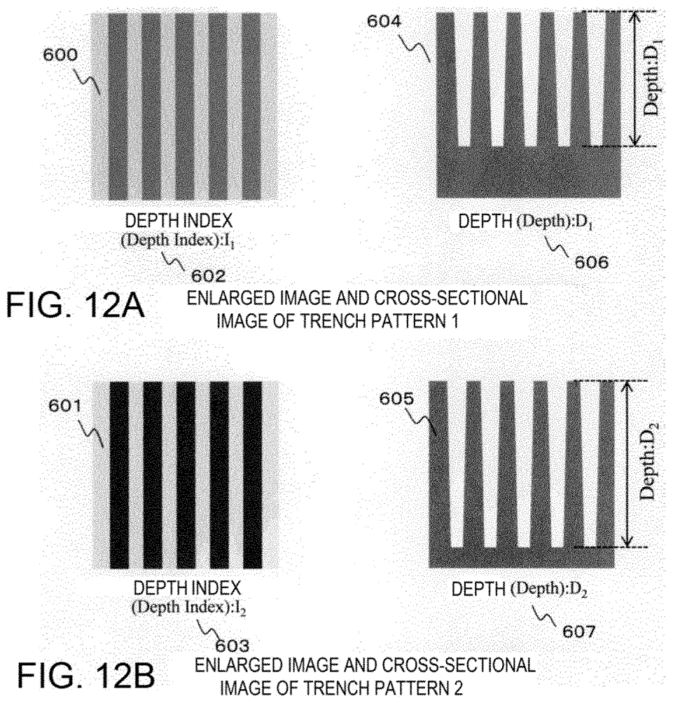

For example, in the case of a trench pattern illustrated in FIGS. 12(a) and 12(b), the depth indexes (I1, I2) 602 and 603 are obtained by substituting the dimension values and the brightness values obtained from the SEM images 600 and 601 into the calculation expressions such as Equation 3 and Equation 4, and the depths (D₁, D₂) 606 and 607 are measured from the cross-sectional images 604 and 605. In this way, by using the methods of measuring the depth of the target pattern in combination, relationship information between the depth index and the depth as illustrated in FIG. 11(a) is generated and stored as a database. More specifically, with respect to a plurality of target patterns, an actual measurement value of a depth and a depth index obtained by a calculation using a calculation expression such as Equation 3 and Equation 4 are measured, an approximation curve indicating a change in the actual measurement value with respect to a change in the depth index is generated, and the approximation curve or an optimal function is stored in the predetermined storage medium, and thereby the database is formed.

Furthermore, the index N 701 used for the calculation of Equation 3 and Equation 4 is stored in combination in the database. The index N 701 is obtained as follows, and is stored in the predetermined storage medium so as to be applied to the calculation at the time of the depth measurement. For example, in a case where a measurement target pattern of the depth measurement has a hole shape (for example, a closed figure hole pattern such as a circular shape), since a solid angle at which an opening is viewed from a hole bottom portion is substantially proportional to a hole area, that, is, the square of a hole diameter, and is proportional to a depth of the hole, the index N is 0.5 on an assumption that the brightness value GL is also substantially proportional to the square of the hole diameter and is proportional to the depth of the hole. That is, a depth (D) can be obtained based on Equation 5.

D=(A/GL)^{0.5} [Equation 5]

In a case where the depth measurement target pattern has a trench shape, since a solid angle at which an opening is viewed from a trench bottom portion is substantially proportional to a trench width and is proportional to a depth of the trench, the index N is 1.0 on an assumption that the brightness value GL is also substantially proportional to the trench width and is proportional to the depth of the trench. That is, the depth (D) can be obtained based on Equation 6.

D=W/GL [Equation 6]

As described above, by registering an appropriate index, corresponding to the shape and the type of the pattern, in advance according to the type of the pattern, an appropriate depth measurement can be performed according to the measurement target.

On the other hand, the inventors have found from a scattering simulation and an experiment of the electron beam that n is generally a positive number but does not necessarily coincide with the ideal value of 0.5 or 1.0 as described above. Therefore, it is desirable to obtain, by a simulation, an experiment, or the like, an appropriate N value corresponding to the pattern to be measured.

As a specific procedure for constructing the database as described above, first, the depth indexes (depth indexes) I1 and I2 are measured by performing a measurement as illustrated in FIG. 5 for the trench patterns 600 and 601 as illustrated in FIG. 12. Next, heights (depths) D₁ and D₂ of the trench patterns are measured from a cross-sectional observation image or the like.

The measurement as described above is executed for a plurality of patterns of the same type, the relationship information between the depth index 610 and the depth 611 is generated, and a database in which the relationship information and the index 612 obtained based on the method described above are stored in association with each other is stored in the predetermined storage medium. The database may store identification information 614 in combination, and may be set such that the depth measurement conditions can be selected by selecting a selection button 615 on the GUI screen illustrated in FIG. 11(b).

The signal processing unit 103 or the depth calculation unit 2505 read out the database (depth measurement conditions) set as described above in step 161 in FIG. 6, and apply the database to the subsequent calculation processing.

In a case of a depth measurement using the gray level, the gain of the photoelectron multiplier tube and the offset of the amplifier are fixed such that the luminance and the contrast of the image do not fluctuate depending on the measurement target. As a method for determining the device conditions in such a manner, although there are the following methods, the invention is not limited thereto.

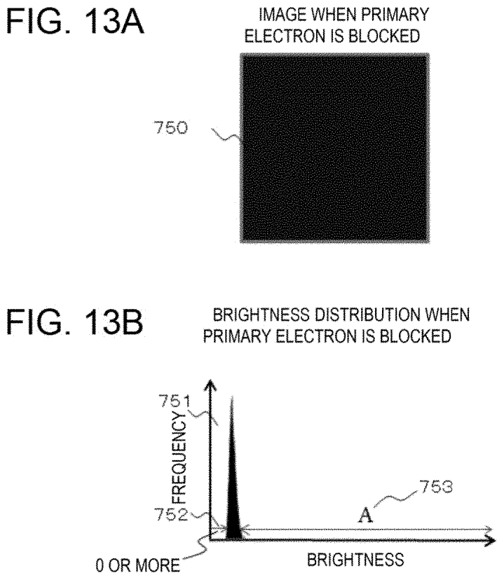

First, a method for determining the device conditions for fixing the luminance will be described. First, the scanning electron microscope as illustrated in FIGS. 1 to 4 is controlled, and an image as illustrated in FIG. 13(a) is generated based on the output of the detector in a state where the sample is not irradiated with an electron beam (electrons emitted from the sample are not detected by the detector) . In order to prevent the arrival of the electron beam at the sample, for example, it is conceivable to close the shutter 130 or deflect the beam off axis (blanking) by the deflector 131.

Next, a brightness histogram of the image as illustrated in FIG. 13(b) is generated. As illustrated in FIG. 13(a), when an image is generated based on the output of the detector in a state where the electrons are not detected, a dark image having substantially zero brightness is generated. In this state, a brightness distribution 751 is determined such that the brightness distribution 751 is not zero brightness (brightness range 752 larger than 0), and a difference A753 from the maximum brightness is sufficiently large. The determined brightness distribution 751, an offset of the amplifier for realizing the brightness distribution, or a luminance value is stored in the predetermined storage medium as the measurement condition (recipe).

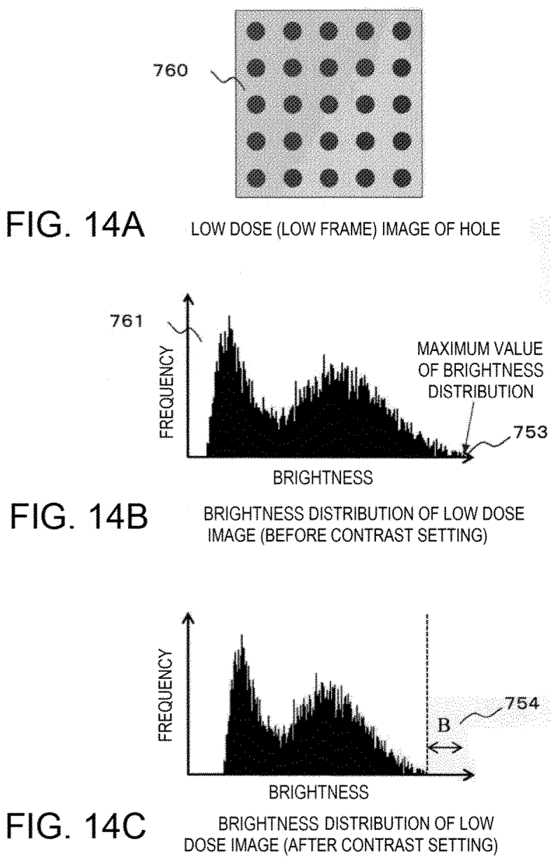

Next, a method for setting an appropriate contrast will be described. First, the sample 112 to be imaged is introduced into the electron microscope, and the stage 113 is controlled such that the view field of the electron microscope is positioned to the depth measurement target pattern. Next, an electron microscope is used to obtain an image 760 as illustrated in FIG. 14. At the time, the smaller a dose amount at the time of image acquisition, the wider the spread of the brightness distribution, and since it is easy to confirm whether the maximum brightness that can be expressed by the device is swung out, images are acquired under low dose (low frame) conditions as compared to normal image generation. At the time of the image generation, an image is generated by setting an offset value acquired by the method described with reference to FIG. 13 in the device. At the time, a brightness histogram as illustrated in FIG. 14(b) is generated, and a gain of the detector is set such that a maximum value 753 of a brightness distribution 761 does not swing out (maximum brightness 754 of the brightness distribution 761 is equal to or less than the maximum brightness that the device can express), or by determining a brightness ratio on a bright side. When the gain (contrast) is to be set, the gain (contrast) can be set for each measurement pattern, or the gain can be set in consideration of measurements of a plurality of different measurement target patterns. Specifically, when a plurality of measurement target, patterns are to be measured, the gain is set such that the maximum brightness is lower than the maximum brightness that can be expressed by the device by a predetermined brightness B 754 in order to avoid swing out of the maximum value of the brightness distribution. The predetermined brightness B 754 may be determined by a numerical value, a percentage, or the like. The gain or contrast value determined in this way is stored in a predetermined storage medium as the measurement condition at the time of the depth measurement.

The overall control unit 102 and the signal processing unit 103 provided in the scanning electron microscope as illustrated in FIGS. 1 to 4 set the luminance and the contrast value in step 152, when performing an automatic depth measurement according to the flowcharts illustrated in FIGS. 5 and 6, and performs the depth measurement based on the gray level, obtained in a state where the setting is performed, and the width or the area.

FIG. 15 shows an example of a GUI screen for setting the luminance value and the contrast value. The GUI screen as illustrated in FIG. 15 is displayed on the input and output unit 104 or a display device provided separately, and information (parameters) input from the GUI screen is sent to the overall control unit 102 and the signal processing unit 103, and control and signal processing corresponding to the input parameters is performed.

In order to set the luminance and contrast, first, the recipe button 651 on the screen 650 illustrated in FIG. 9(a) is pressed to open the recipe setting screen 660 (FIG. 9(b)). When the pattern recognition button 662 is pressed on the GUI screen, the pattern recognition screen 800 illustrated in FIG. 15(a) is opened. On the pattern recognition screen 800, there is an ABC item 801 for setting the luminance and the contrast, and auto luminance contrast control (ABCC) 802 is selected in a case of automatic setting and switching is possible by selecting fix-ABC 803 in a case of fixing the luminance and the contrast.

When fix-ABC 803 is selected, a detailed setting button 304 is enabled, and when the button is pressed, a fix-ABC setting screen 810 illustrated in FIG. 15(b) is opened. On this screen, by using the method shown above, the signal processing unit 103 adjusts the gain and the offset of the detector and the amplifier, and automatically obtains a luminance value 812 and a contrast value 821. When a brightness button 811 is pressed on the fix-ABC setting screen 810, the overall control unit 102 sets the luminance according to the procedure as described above, and stores the device parameters (offset) at that time in a predetermined storage medium. The luminance values corresponding to the device parameters are displayed in 805 and 812. When the luminance is desired to be set freely, a value can be input into 812.

When an image button 813 provided on a GUI screen illustrated in FIG. 15(b) is pressed, the image operation screen 830 illustrated in FIG. 15(c) is displayed, and an image 831 at the time of setting the luminance value (the image when the primary electrons are blocked illustrated in FIG. 13(a) is displayed) can be confirmed. When a profile button 814 is pressed, a profile screen 840 illustrated in FIG. 15(d) is displayed, and a brightness distribution 84i at the time of setting the luminance value can be confirmed.

When a contrast button 820 is pressed on the fix-ABC setting screen 810 illustrated in FIG. 15(b), the contrast value is set in the above-described procedure, and the device parameter (gain) at that time is stored in the predetermined storage medium. The contrast value corresponding to the device parameter is displayed in 806 or 821. When a contrast value is desired to be set freely, a value can be input into 821.

When information of a pattern to be measured is registered, coordinate information of the pattern is input. Specifically, coordinates of the pattern can be stored by pressing a registration button 822 provided on the GUI screen illustrated in FIG. 15(b). The coordinates can be confirmed at. a position 824. When a measurement position is desired to be set freely, the coordinates of the pattern can be input to a position 824. A move button 823 for moving the measurement target coordinates is provided on the GUI screen illustrated in FIG. 15(b), and the measurement position may be set based on selection of the button. When an image button 825 is pressed, the image operation screen 830 illustrated in FIG. 15(c) is displayed, and the image 831 in which the luminance value and the contrast value are set can be confirmed. When a profile button 826 is pressed, a profile screen 840 illustrated in FIG. 15(d) is displayed, and a brightness distribution 841 at the time of setting the luminance value can be confirmed.

Next, specific processing contents for calculating the depth index of the pattern based on the database and the device parameter set as described above will be described. Processing to be described later is performed by the signal processing unit 103 and the computer system 2502. A specific method of performing depth measurement based on the brightness of the pattern, the pattern width, or the area will be described below.

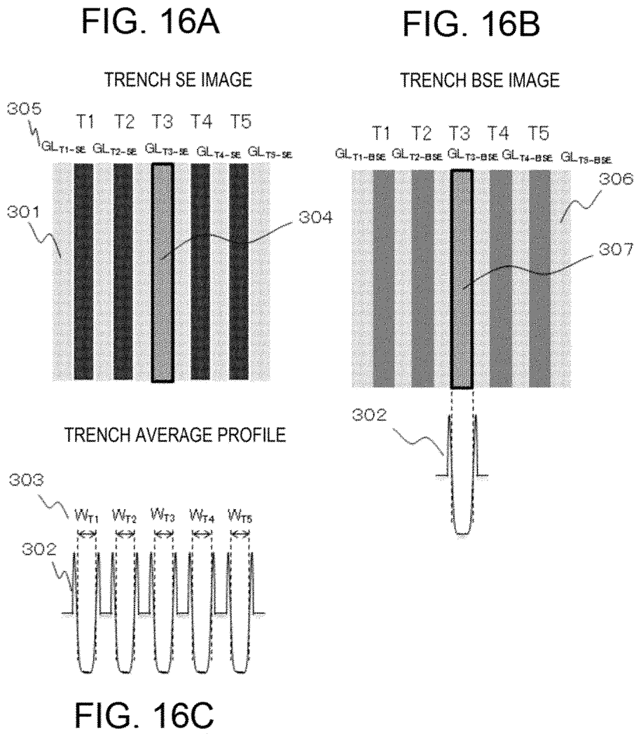

FIG. 16(a) shows an example of an image acquired in step 154 in FIGS. 5 and 6. An image 301 is a secondary electron (SE) image. In order to obtain the depth index, in steps 155 and 156, a brightness value 305 (GL_{TX-SE}) of the trench (region 304) and a width 303 (W_{TX}) of the trench are obtained using the image 301. The brightness value 305 is calculated from, for example, a brightness value at a position corresponding to a trench (groove) of a profile waveform 302. In this example, an average GL_{TAve-SE} of the brightness of the trench included in the image 301 is set as the brightness value of the trench in the image 301. Further, an average value W_{TAve} of the widths is set as a width value of the trench in the image 301.

FIG. 16(b) shows an example of the image acquired in step 154 in FIGS. 5 and 6. An image 306 is a backscattered electrons (BSE) image. Similarly to the SE image, a trench width (W_{TX}, W_{TAve}) 303 is measured. In this case, an average signal waveform obtained by averaging an addition of the signal waveforms obtained in the trenches may be generated, and a dimension value between peaks may be obtained on the average signal waveform. Further, a brightness value GL_{TxAve-BSE} and a brightness average value GL_{TAve-BSE} of a region 307 recognized by a trench width measurement are calculated.

When a scanning electron microscope is provided with a plurality of detectors that simultaneously detect SE and BSE, a trench region may be specified in the SE image, and an average brightness of BSE in the specified trench region may be obtained. When the contrast of the BSE image is low, the trench width (W_{Tx}, W_{TAve}) may be measured using the SE image, or vice versa.

In step 158, the depth indexes (IT-SE, IT-BSE) are calculated using the trench width, the brightness value obtained as described above, and Equation 7 or Equation 8.

I_{T-SE}=(W_{Tx-SE, BSE}/GL_{Tx-SE})^{N} [Equation 7]

I_{T-BSE}=(W_{Tx-SE, BSE}/GL_{Tx-BSE})^{N} [Equation 8]

When the brightness average value GL_{TAve-SE} or GL_{TxAve-BSE} is used as the brightness value, the depth index is calculated using Equation 9 or Equation 10.

I_{T-SE}=(W_{Tx-SE, BSE}/GL_{TAve-SE})^{N} [Equation 9]

I_{T-BSE}=(W_{Tx-SE, BSE}/GL_{TxAve-BSE})^{N} [Equation 10]

Further, when an average trench width W_{TAve} of the plurality of trenches is set to the trench width, the depth index is calculated using Equation 11 or Equation 12.

I_{T-SE}=(W_{TAve-SE, BSE}/GL_{TAve-SE})^{N} [Equation 11]

I_{T-BSE}=(W_{TAve-SE, BSE}/GL_{TxAve-BSE})^{N} [Equation 12]

As described above, by performing the depth measurement based on the two pieces of information including the brightness value and the dimension value (the width of the trench in the above-described example), accurate depth measurement can be performed regardless of a difference in the material and the pattern density of the sample.

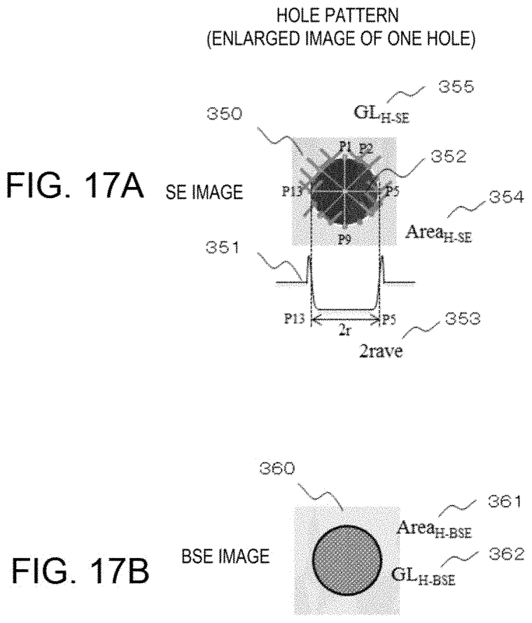

Next, an example of measuring the depth of the hole pattern will be described. FIG. 17(a) shows an example of the secondary electron image (SE image) acquired in step 154. The image illustrated in FIG. 17(a) includes one hole pattern 350. In the case of a trench, a line width is measured as a shape index value, but in the case of a closed figure such as a hole pattern, an area of the hole is measured. Specifically, edge positions (P1 to Pn) are specified from a brightness profile 351 of the obtained image, and a dimension 2r between peaks on the brightness profile is obtained for a plurality of directions. An average value 2rₐᵥₑ 353 is calculated by averaging a plurality of 2r, πrₐᵥₑ² is solved, and thereby an area Area_{H-SE} 354 of the holes is obtained (step 155). Further, a brightness GL_{H-SE} 355 in the edge (inside the hole) is measured (step 156). The brightness may be obtained by averaging the brightness of a predetermined region (for example, an internal region having points that are separated from the edge by a predetermined distance as a boundary line) inside the edge.

FIG. 17(b) shows an example of a backscattered electron image (BSE image) of a hole pattern 360. Similarly to the SE image, an area Area_{H-BSE} 361 and a brightness GL_{H-BSE} 362 are measured.

When the brightness value is calculated using the BSE image simultaneously captured with the SE image, the brightness GL_{H-BSE} 362 may be measured in the same region as the region 354 recognized in an area calculation of the SE image. The area measurement and the brightness measurement may not use the same image.

The depth index is calculated by substituting the area value and the brightness value obtained in the manner described above (for example, measuring the area with the SE image and measuring the brightness with the BSE image) into Equation 13 and Equation 14.

I_{H-SE}=(Area_{H-SE, BSE}/GL_{H-SE})^{N} [Equation 13]

I_{H-BSE}=(Area_{H-SE, BSE}/GL_{H-BSE})^{N} [Equation 14]

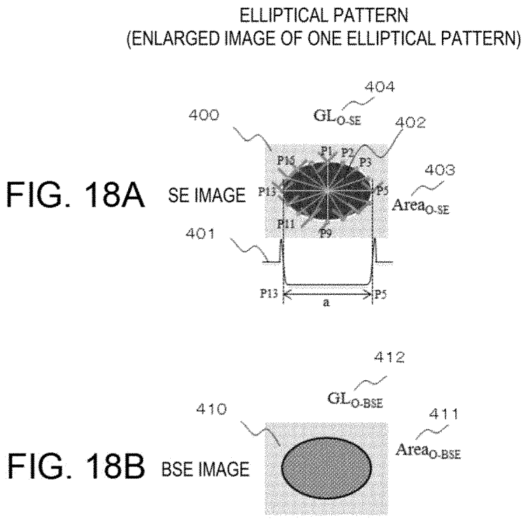

FIG. 18 shows an example of an elliptical pattern image. FIG. 18(a) shows an example of an SE image, and FIG. 18(b) shows an example of a BSE image. Similar as the hole pattern, the brightness and area of the bottom of the elliptical pattern are measured. In the case of an ellipse, dimension values of diameters (for example, 402) in a plurality of directions are obtained from a brightness profile 401 in the plurality of directions, a maximum value a (P5-P13 in the example of FIG. 18(a)) and a minimum value b (P1-P9 in the example of FIG. 18(a)) are extracted, nab is solved, and thereby an Area_{O-SE} is obtained. Brightness GL_{O-SE} of an interior of the ellipse is calculated. Similarly, in the BSE image, an area Area_{O-BSE} of an elliptical pattern 410 and the brightness GL_{O-BSE} of an interior of the ellipse are obtained. By substituting the brightness and area obtained as described above into (area/brightness)n, the depth index is calculated. When the brightness value is calculated using the BSE image simultaneously captured with the SE image, the brightness average value may be measured in the same region as the region recognized in the area calculation of the SE image.

In FIG. 10, areas (Area_{S/R-SE} 503, Area_{S/R-BSE} 511) and internal brightness (GL_{3/R-SE} 504, GL_{3/R-BSE} 512) are respectively obtained from square or rectangular patterns 500 and 510, and the depth index is calculated from (area/brightness)^{N}. The area can be calculated by multiplying dimensional values a and b obtained from a brightness profile 501 in an x direction and a brightness distribution 502 in a y direction.

When the brightness value is calculated using the BSE image simultaneously captured with the SE image, the brightness average value may be measured in the same region as the region recognized in the area calculation of the SE image.

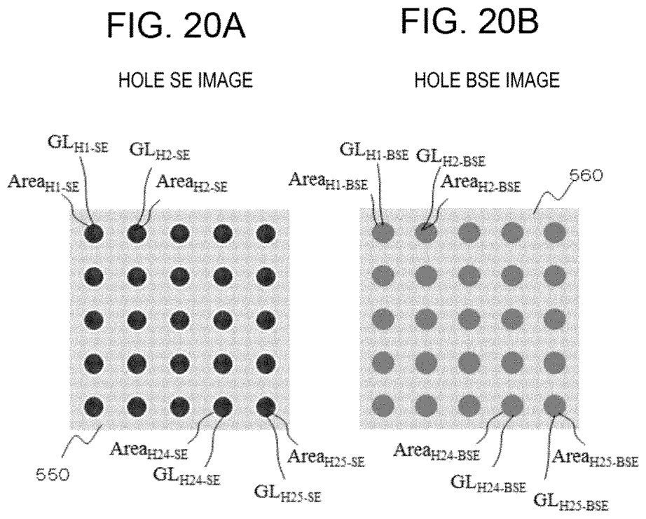

Next, a depth index measurement method when a plurality of patterns are included in the field of view will be described. FIG. 20 is a diagram showing an example of an SEM image in which a plurality of patterns (25 hole patterns) are included in the field of view, FIG. 20(a) shows an example of the SE image 550, and FIG. 20(b) shows an example of the BSE image 560. When a plurality of patterns are included in the field of view in this way, average area values (Area_{H-SE-Ave}, Area_{H-BSE-Ave}) are obtained using Equations 15 and 16. A_{H1-SE} . . . , Area_{H1-BSE} . . . are area values of each hole obtained based on image processing.

Area_{H-SE-Ave}=Average(A_{H1-SE}+A_{H2-SE}+A_{H3-SE}+ . . . +A_{Hn-SE}) [Equation 15]

Area_{H-BSE-Ave}=Average(A_{H1-BSE}+A_{H2-BSE}+A_{H3-BSE}+ . . . +A_{Hn-BSE}) [Equation 16]

Average values of the brightness values (GL_{H-SE-Ave}, GL_{H-BSE-Ave}) are calculated using Equations 17 and 18. GL_{H1-SE} . . . , GL_{H1-BSE} . . . are brightness values of a region including a center portion of each hole obtained based on the image processing.

GL_{H-SE-Ave}=Average(GL_{H1-SE}+GL_{H2-SE}+GL_{H3-SE}+ . . . +GL_{Hn-SE}) [Equation 17]

GL_{H-BSE-Ave}=Average(G_{LH1-BSE}+G_{LH2-BSE}+G_{LH3-BSE}+ . . . +GL_{Hn-BSE}) [Equation 18]

Based on the average area values (Area_{H-SE-Ave}, Area_{H-BSE-Ave}) and the average brightness values (GL_{H-3E-Ave}, GL_{H-BSE-Ave}) obtained as described above, the depth indexes I_{H-SE-Ave} and I_{H-BSE-Ave} are calculated using Equations 19 and 20.

I_{H-SE-Ave}=(Area_{H-SE-Ave}/GL_{H-SE-Ave})^{N} [Equation 19]

I_{H-BSE-Ave}=(Area_{H-BSE-Ave}/GL_{H-BSE-Ave})^{N} [Equation 20]

As another depth index measurement in the case where a plurality of patterns are included in the field of view, there is also a method of calculating depth indexes using the area and the brightness for each pattern, and using Equations 21 and 22. (A_{H1-SE}/GL_{H1-SE}) . . . , (A_{H1-BSE}/GL_{H1-BSE}) . . . are depth indexes of each hole obtained based on the image processing.

I_{H-SE-Ave}=Average((A_{H1-SE}/GL_{H1-SE})+(A_{H2-SE}/GL_{H2-SE})+(A_{H3-BSE}/GL_{H3-BSE})+ . . . +(A_{Hn-SE}/GL_{Hn-SE}) [Equation 21]

I_{H-BSE-Ave}=Average((A_{H1-BSE}/GL_{H1-BSE})+(A_{H2-BSE}/GL_{H2-BSE})+(A_{H3-BSE}/GL_{H3-BSE})+ . . . +(A_{Hn-BSE}/GL_{Hn-BSE}) [Equation 22]

As illustrated in FIG. 20, when a plurality of identical shape patterns exist in the field of view, a highly accurate height evaluation can be performed by performing the above-described calculation. On the other hand, when depths of the plurality of patterns in the field of view are to be compared, the depth index may be calculated based on the individual area values and brightness values, or the average area value and average brightness value of the plurality of region units.

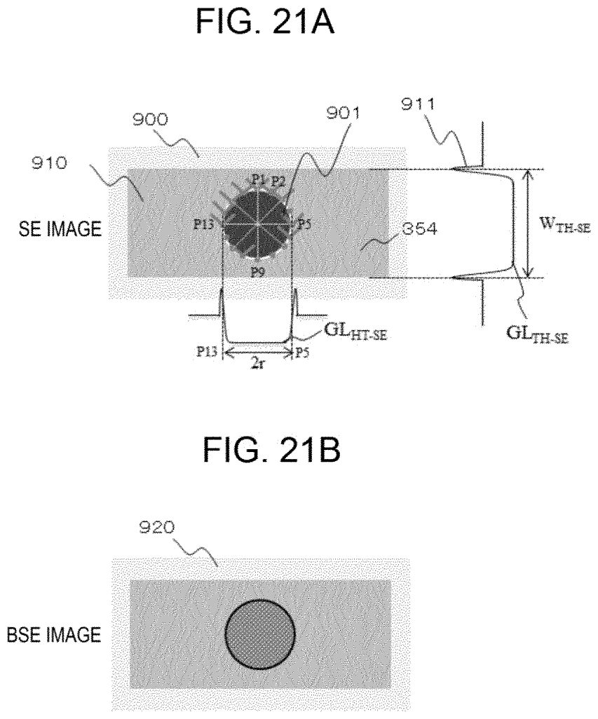

FIG. 21 shows an example of an electron microscope image of a via in trench in which a hole pattern (via) is formed in a lower portion of a trench (groove shaped pattern). FIG. 21(a) illustrates an SE image 900, and FIG. 21(b) illustrates a BSE image 920. FIG. 21 illustrates the images acquired in step 154 of the flowchart illustrated in FIGS. 5 and 6. As illustrated in FIG. 21(a), it can be seen on the electron microscope image, a hole pattern 901 exists inside a trench 910. In order to calculate a depth index of such a pattern, a hole pattern area Area_{HT-SE} 903 is obtained based on the calculation expression used in the description of FIG. 17, and a width W_{TH-SE} 912 of the trench 910 is obtained using a brightness profile 911. Further, brightness GL_{HT-SE} 904 of an interior of the hole pattern 901 and brightness GL_{TH-SE} 913 inside the trench 910 excluding the hole pattern region are measured.

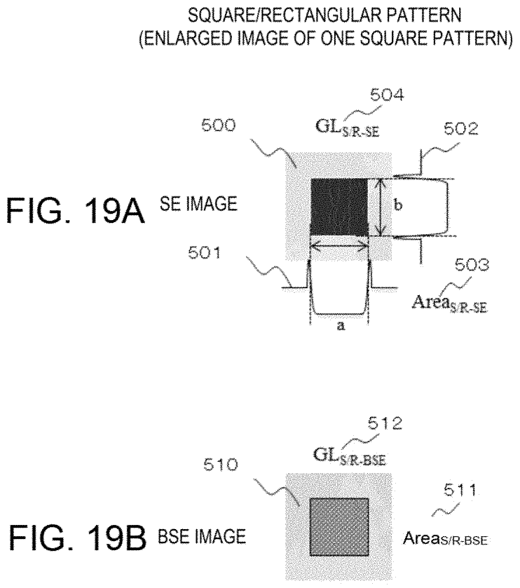

When the depth index is calculated using the BSE image 920 illustrated in FIG. 19(b), the area Area_{HT-BSE} of the hole, the trench width W_{TH-BSE}, the brightness GL_{HT-BSE} of the hole, and the brightness GL_{TH-BSE} of the trench are also measured in the same manner as the SE image. When the brightness value is calculated using the BSE image simultaneously captured with the SE image, a brightness value or an average brightness value within a region of a hole or a trench specified by the SE image can also be measured, and vice versa. The area measurement and the brightness measurement may not use the same image. By substituting the area value, the dimension value, and the brightness value obtained as described above (for example, the area and the width are measured in the SE image, and the brightness is measured in the BSE image) into (area or dimension value/brightness value)^{N} stored in advance, the depth index of the hole or the trench can be obtained. When a dimension in a longitudinal direction of the trench is small (for example, when the entire trench is displayed in the field of view), the trench may be regarded as a rectangle, and the depth index may be calculated based on the calculation of the area value (a dimension value of a width of the trench×a dimension value of the trench in the longitudinal direction) as illustrated in FIG. 19.

When a via in trench and a simple via are compared with each other, the simple via is a thin cylindrical body from a hole bottom to a surface of the sample, whereas in the case of the via in trench, since a trench is formed in the middle (a space is opened in the middle), electrons emitted from the hole bottom easily escape to the surface of the sample as compared with the simple via, and it is considered that the via trench is relatively bright. Therefore, by preparing the N value corresponding to a pattern formation condition (presence or absence of an upper layer and an area or dimension value of an upper layer pattern), the depth index can be calculated with high accuracy regardless of a state of the upper layer. A correction coefficient for correcting the brightness value of the bottom portion may be prepared in advance in accordance with a formation state of the pattern, and brightness correction may be performed based on a selection of the formation state of the pattern, and thereby the brightness corresponding to the depth may be accurately obtained regardless of the formation state of the upper layer. In the case of the via in trench, a plurality of models having different N in a via and a trench may be prepared, and may be selectively used depending on a measurement purpose. Even if the dimension (depth) between the via and the sample surface is the same, brightness of a via bottom changes when the depth of the trench is different, so that processing may be considered in which the depth of the trench is measured first and brightness of a hole bottom or a depth index of the via is corrected in accordance with the depth.

Although FIGS. 16 and 17 both illustrate examples in which the brightness of the trench bottom or the hole bottom is lower than the brightness of the sample surface, the brightness at the trench bottom or the hole bottom may be higher depending on a material of a pattern positioned at the trench bottom or the hole bottom or the device conditions of the electron microscope. In such a case, depth estimation using a mathematical model such as Equation 1 can also be performed. In particular, since the brightness of the bottom may be high in the BSE image, an algorithm for automatically selecting whether to obtain a brightness value of a high brightness region or a brightness value of a low brightness region in accordance with the selection of at least one of the material constituting the sample and the detection condition (in particular, the SE detection or the BSE detection), and thereby the depth estimation can be performed based on the brightness evaluation at an appropriate region.

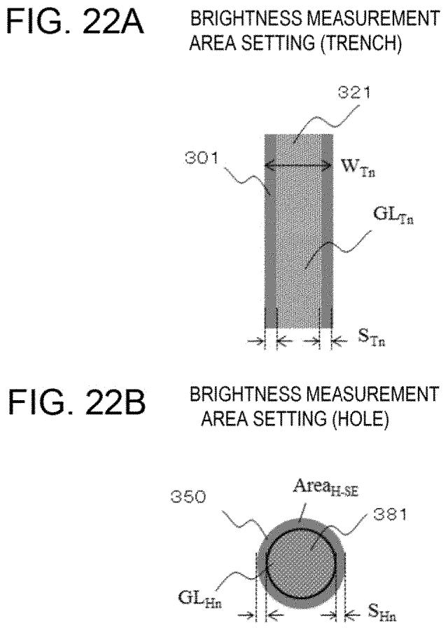

In order to appropriately evaluate the depth of the bottom of the hole or the trench, it is desirable to selectively evaluate only the bottom portion not including the edge of the pattern or the like. It is necessary, in a depth evaluation method using a principle that the luminance of the bottom portion changes according to the depth of the hole or the trench, to appropriately evaluate the luminance of the bottom portion. Therefore, as illustrated in FIG. 22, a trench region or a hole region narrower or smaller than the line width and the hole diameter may be selected. Specifically, as illustrated in FIG. 22(a), a width W_{Tn} of a trench 301 displayed in the SEM image is measured, and a brightness evaluation region (width S_{Tn}) is set in a manner of being narrower than W_{Tn}. Then, brightness GL_{Tn} of a bottom portion 321 is evaluated. The hole pattern is also the same, and as illustrated in FIG. 22(b), for a hole 350, a hole area Area_{H-SE} is obtained based on a calculation of hole diameters in a plurality of directions, arid a region which is narrower than the Area_{H-SE} by a range of 2S_{Hn} is set as the brightness evaluation region. Then, the brightness GL_{Tn} of a bottom portion 381 is set. Examples of a method of narrowing the region include a method of specifying the number of pixels and a dimension corresponding to a narrowed amount. By performing the brightness evaluation in which range narrowing is performed in this way, it is possible to perform a highly accurate depth evaluation. Even if the measurement is not performed, the edge may be extracted based on a brightness profile and a frame of the evaluation region may be set at a position separated from the edge by a predetermined amount.

In addition, as another method for setting the brightness evaluation region, for a trench pattern, a line profile showing a brightness distribution in a direction orthogonal to a longitudinal direction of the trench pattern may be formed, a dark part in the line profile (for example, a part with brightness lower than a predetermined threshold) may be specified, a center of the dark region is specified, and average brightness for a predetermined number of pixels with the center as a reference may be defined as brightness at a trench bottom. Unlike the SE image, the BSE image may have a higher brightness at the trench bottom than at the sample surface depending on the type of material located at the trench bottom as described above. Therefore, by preparing an algorithm for specifying the high brightness region, specifying the center of the high brightness region, and setting the brightness evaluation region with reference to the center of the high brightness region, highly accurate depth estimation can be performed based on the selection of an appropriate brightness evaluation region A size of the brightness evaluation region can be set by the number of pixels and the dimensional value, and thus an appropriate brightness evaluation region corresponding to the quality of the sample can be selected. The brightness evaluation region can be selected by using the above method even in a closed figure such as a hole pattern or a structure such as a via in trench in which a hole pattern (via) is formed in a lower part of the trench (groove shaped pattern).

Next, an output example of the depth measurement result will be described. FIG. 23 shows a display example of the measurement result. By pressing the result button 653 on the screen 650 illustrated in FIG. 9, the result screen 850 is displayed, and the result of the depth measurement can be confirmed. When a measurement data button 851 is pressed, a measurement data list 860 (FIG. 23(b)) is displayed. In the list, an image name 861, image acquisition coordinates 862, measurement results 863, and the like are displayed. When the list is selected 864 from the measurement data list 860 and the list is clicked, a captured image 870 is displayed on the image operation screen 830 (FIG. 23(c)). When a Re-MS button 371 is pressed, the measurement screen 670 is displayed, and the measurement result can be confirmed or re-measured. When the result is to be changed to a re-measured result, a save button 872 is pressed and the result is reflected in the measurement data list 860.

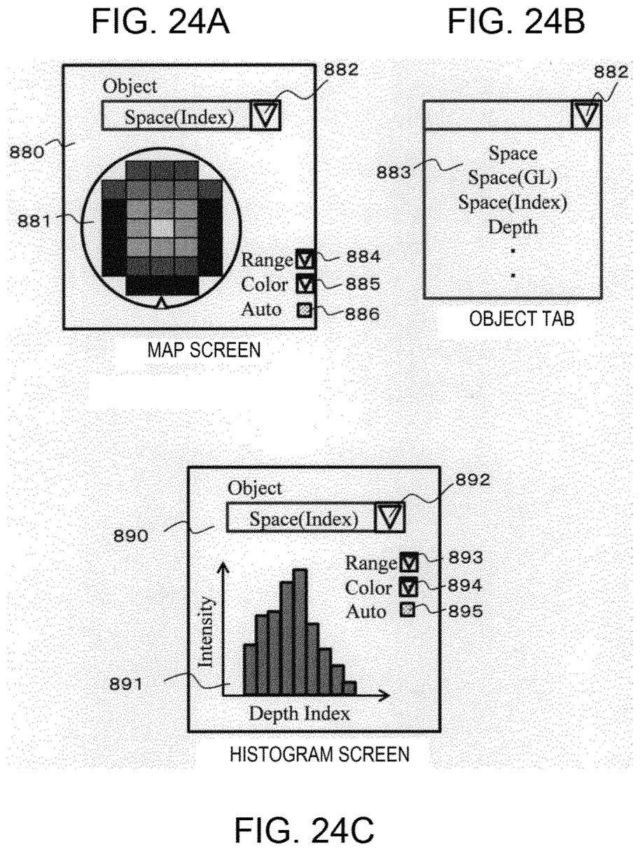

When an MAP button 852 of the result screen 850 illustrated in FIG. 23(a) is pressed, a MAP screen 880 illustrated in FIG. 24(a) is displayed, and a distribution 881 of a wafer or shot whose depth has been measured can be confirmed The measurement results to be confirmed in a distribution can be selected on an object tab 882 illustrated in FIG. 24(b), and a distribution of each measurement result 883 can be confirmed. A range to be displayed in a distribution can be selected in a range tab 884, and a color at that time can be selected in a color tab 985. When an Auto button 886 is pressed, a display range and a color to be displayed can be automatically determined according to each measurement result.

When a histogram button 853 of the result screen 850 illustrated in FIG. 23(a) is pressed, a histogram screen 890 illustrated in FIG. 24(c) is displayed, and the depth measurement result can be confirmed in a histogram. The measurement result to be confirmed in a histogram can be selected on an object tab 892, and the histogram of each measurement result can be confirmed as in the measurement result selection screen illustrated in FIG. 24(b). A range to be displayed in a distribution can be selected on a range tab 893, and a color at that time can be selected on a color tab 894. When an Auto button 895 is pressed, a display range and a color to be displayed can be automatically determined according to each measurement result.

### REFERENCE SIGN LIST

101: imaging unit (scanning electron microscope)
102: overall control unit
103: signal processing unit
104: input and output unit
105: storage unit
106: electron gun
107: electron beam
108: focusing lens
109: focusing lens
110: deflector
111: objective lens
111, 112: sample
113: stage
114: emitted electron
115: deflector
116: detection aperture
117: reflecting plate
118: secondary electrons
119: detector
120: secondary electrons
121: detector
123: energy filter

1. A method comprising:
acquiring, by using a measurement tool, an image or brightness distribution of a region including a recess formed in a sample;
extracting, from the acquired image or brightness distribution, a first characteristic of an interior of the recess, and a second characteristic related to a dimension or area of the recess, and
inputting the extracted first characteristic and second characteristic into a model indicating a relationship between the first characteristic, the second characteristic, and a depth index of the recess to derive the depth index of the recess.

2. The method according to claim 1, wherein
the recess is a trench, a via, or both.

3. The method according to claim 1, wherein
the first characteristic is a value related to brightness of a bottom of the recess.

4. The method according to claim 3, wherein
the value related to the brightness is acquired in a region narrower than the recess in dimension or area.

5. The method according to claim 1, wherein
the recess is a closed figure pattern, and the depth index is derived based on the following calculation expression
depth index=(value related to area of closed figure pattern/value related to brightness of interior of closed figure pattern)^{N} (N being any positive number).

6. The method according to claim 5, wherein
N is 0.5.

7. The method according to claim 1, wherein
the recess is a trench shaped pattern, and the depth index is derived based on the following calculation expression
depth index=(value related to dimension of trench width/value related to brightness of interior of trench)^{N} (N being any positive number).

8. The method according to claim 7. wherein
N is 1.0.

9. The method according to claim 1, wherein
a pattern depth is derived based on the derived depth index by referring to a database in which relationship information between the depth index and die pattern depth is stored.

10. The method according to claim 1, wherein
the image or the brightness distribution is obtained based on scanning of a charged particle beam, and a penetration depth of the charged particle beam is shorter than a film thickness of a film in which the recess is formed, which is a derivation target of the depth index.

11. A system comprising:
a measurement tool configured to acquire an image or brightness distribution of a region including a recess formed in a sample; and
a computer configured to execute a computer-readable program to derive, from the acquired image or brightness distribution, a first characteristic of an interior of the recess, and a second characteristic related to a dimension or area of the recess, wherein
the computer is further configured to execute a computer-readable program to derive a depth index by using the extracted first characteristic and second characteristic, and a model indicating a relationship between the first characteristic, the second characteristic, and the depth index.

12. The system according to claim 11, wherein
the measurement tool is configured to acquire first information in a region narrower than the recess in dimension or area.

13. The system according to claim 11, comprising:
an input device configured to select a type of the recess, wherein
the computer is configured to derive the depth index by using a model corresponding to a type of the recess input by the input device.

14. The system according to claim 11, wherein
the computer is configured to, when a type of the recess is a closed figure pattern, derive a value related to an area of the closed figure pattern as the second characteristic.

15. The system according to claim 14, wherein the computer is configured to derive the depth index based on the following calculation expression
depth index=(value related to area of closed figure pattern value related to brightness of interior of closed figure pattern)^{N} (N being any positive number).

16. The system according to claim 11, wherein
the computer is configured to, when a type of the recess is a trench shaped pattern, derive a value related to a width of the trench shaped pattern as the second characteristic.

17. The system according to claim 16, wherein
the computer is configured to derive the depth index based on the following calculation expression
depth index=(value related to dimension of trench width/value related to brightness of interior of trench)^{N} (N being any positive number).

18. The system according to claim 11. wherein
the computer is configured derive a pattern depth based on the derived depth index by referring to a database in which relationship information between the depth index and the pattern depth is stored.

19. A non-temporary computer-readable medium that stores a program command executable in a computer system for executing a computer-executable method for generating, based on an image or brightness distribution obtained by a measurement tool, depth information of a recess formed in a sample, wherein
the computer-executable method includes:
acquiring, by using a measurement tool, an image or brightness distribution of a region including a recess formed in a sample:
extracting, from the acquired image or brightness distribution, a first characteristic of an interior of the recess, and a second characteristic related to a dimension or area of the recess; and
inputting the extracted first characteristic and second characteristic into a model indicating a relationship between the first characteristic, the second characteristic, and a depth index of the recess to derive the depth index of the recess.
